(19) United States
(12) Patent Application Publication
(10) Pub. No.: US 2024/0215363 A1
(43) Pub. Date: Jun. 27, 2024

(54) DISPLAY APPARATUS

(71) Applicant: Samsung Display Co., Ltd., Yongin-si (KR)

(72) Inventors: Sunhwa Lee, Yongin-si (KR); Heejean Park, Yongin-si (KR); Hyeongseok Kim, Yongin-si (KR); Junhyun Park, Yongin-si (KR)

(21) Appl. No.: 18/467,582

(22) Filed: Sep. 14, 2023

(30) Foreign Application Priority Data
Dec. 21, 2022 (KR) 10-2022-0180884

(51) Int. Cl. H10K 59/131; H10K 59/121

(52) U.S. Cl. CPC H10K 59/1315; H10K 59/1213; H10K 59/1216

(57) ABSTRACT

A display apparatus includes a display area configured to display an image using a pixel, and a peripheral area at least partially surrounding the display area, a pad portion in the peripheral area, and including pads, a first power voltage line between the display area and the pad portion in plan view, and including first power patterns spaced apart from each other, and a fan-out wire portion connected between the pad portion and the display area, and overlapping at least a portion of the first power patterns, wherein the fan-out wire portion includes a first fan-out wire, a second fan-out wire, and a third fan-out wire, the second fan-out wire being at a different layer from the first fan-out wire, and the third fan-out wire being at a different layer from the first fan-out wire and from the second fan-out wire.

### CROSS-REFERENCE TO RELATED APPLICATION

This application claims priority to, and the benefit of, Korean Patent Application No. 10-2022-0180884, filed on Dec. 21, 2022, in the Korean Intellectual Property Office, the disclosure of which is incorporated by reference herein in its entirety.

### BACKGROUND

### 1. Field

One or more embodiments relate to a display apparatus.

### 2. Description of the Related Art

Display apparatuses may visually display data. A display apparatus includes a substrate divided into a display area, and a peripheral area outside the display area. In the display area, a scan line and a data line are formed insulated from each other, and a plurality of pixels are arranged to be connected to the scan line and the data line. Also, a transistor and a pixel electrode electrically connected to the transistor may be provided in the display area to correspond to each of the pixels. In addition, an opposite electrode commonly provided to the pixels is provided in the display area. Various wires, a scan driver, a data driver, a controller, etc. each transmitting an electric signal to the display area may be provided in the peripheral area.

Display apparatuses have been used for various purposes. Accordingly, research on methods to reduce, or to efficiently use, a peripheral area of a display apparatus have been actively conducted.

### SUMMARY

One or more embodiments provide a display apparatus having a reduced peripheral area and excellent display quality. However, the embodiments are only examples, and do not limit the scope of the disclosure.

Additional aspects will be set forth in part in the description which follows and, in part, will be apparent from the description, or may be learned by practice of the presented embodiments.

According to one or more embodiments, a display apparatus includes a substrate including a display area configured to display an image using a pixel, and a peripheral area at least partially surrounding the display area, a pad portion in the peripheral area, and including pads, a first power voltage line between the display area and the pad portion in plan view, and including first power patterns spaced apart from each other, and a fan-out wire portion connected between the pad portion and the display area, and overlapping at least a portion of the first power patterns, wherein the fan-out wire portion includes a first fan-out wire, a second fan-out wire, and a third fan-out wire, the second fan-out wire being at a different layer from the first fan-out wire, and the third fan-out wire being at a different layer from the first fan-out wire and from the second fan-out wire.

The first power patterns may be arranged in a first direction.

The first power patterns may include a first connection line connected to the pad portion.

The display apparatus may further include a third power voltage line extending in a first direction between the display area and the first power voltage line, and a third connection line connected to the third power voltage line, and extending in a second direction between the first power patterns.

The third connection line and the first power patterns may be at a same layer.

The display apparatus may further include a first power sub-line extending in a first direction between the first power voltage line and the display area, wherein the first power sub-line is electrically connected to at least one of the first power patterns.

The first power sub-line may be at a different layer from the first power patterns.

The display apparatus may further include a transistor and a storage capacitor in the display area, the transistor including a semiconductor layer, a gate electrode, a source electrode, and a drain electrode, and the storage capacitor including a first electrode and a second electrode, and a driving voltage line above the transistor in the display area, and connected to the first power voltage line.

The first fan-out wire and the source electrode may be at a same layer, wherein the first power patterns and the driving voltage line are at a same layer.

The second fan-out wire and the first electrode may be at a same layer, wherein the third fan-out wire and the second electrode are at a same layer.

The display apparatus may further include a second power voltage line partially overlapping the fan-out wire portion, the second power voltage line and the first power patterns being at a same layer.

The display apparatus may further include an organic light-emitting element in the display area, and including a pixel electrode, an intermediate layer including an organic emission layer, and an opposite electrode.

According to one or more embodiments, a display apparatus includes a substrate including a substrate including a display area for displaying an image using a pixel, and a peripheral area at least partially surrounding the display area, a pad portion in the peripheral area, and including pads, a first power voltage line including first power patterns arranged in a first direction in the peripheral area, and connected to the pad portion, a driving voltage line electrically connected to the first power voltage line, and extending to the display area, a third power voltage line extending in the first direction in the peripheral area, and a third connection line connecting the third power voltage line to the pad portion, crossing between the first power patterns, and at a same layer as the first power patterns.

The display apparatus may further include a first fan-out wire extending from the pad portion to the display area, and overlapping at least a portion of the first power patterns.

The display apparatus may further include a transistor in the display area, and including a semiconductor layer, a gate electrode, a source electrode, and a drain electrode, wherein the first fan-out wire and the source electrode are at a same layer.

The display apparatus may further include a second power voltage line partially overlapping the first fan-out wire, and at a same layer as the first power patterns.

The display apparatus may further include a first power sub-line extending in the first direction between the first power voltage line and the display area, and electrically connected to at least one of the first power patterns.

The first power sub-line may be connected to the driving voltage line.

The first power sub-line may be at a different layer from the first power patterns.

The display apparatus may further include an organic light-emitting element in the display area, and including a pixel electrode, an intermediate layer including an organic emission layer, and an opposite electrode.

### BRIEF DESCRIPTION OF THE DRAWINGS

The above and other aspects of certain embodiments of the disclosure will be more apparent from the following description taken in conjunction with the accompanying drawings, in which:

FIG. 1 is a schematic plan view of a display apparatus according to one or more embodiments;

FIGS. 2A and 2B are equivalent circuit diagrams of a pixel circuit of a display apparatus according to one or more embodiments;

FIG. 3 is an enlarged view of a region A of FIG. 1;

FIG. 4 is a schematic diagram of a cross-section of the display apparatus taken along the line I-I′ of FIG. 1 and the line II-II′ of FIG. 3;

FIG. 5 is a schematic diagram of a cross-section of the display apparatus taken along the line I-I′ of FIG. 1 and the line III-III′ of FIG. 3;

FIG. 6 is an enlarged view of a region A of FIG. 1; and

FIG. 7 is a schematic diagram of a cross-section of the display apparatus taken along the line I-I′ of FIG. 1 and the line IV-IV′ of FIG. 6.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Further, each of the features of the various embodiments of the present disclosure may be combined or combined with each other, in part or in whole, and technically various interlocking and driving are possible. Each embodiment may be implemented independently of each other or may be implemented together in an association. The described embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

A display apparatus displays an image, and may include a liquid crystal display apparatus, an electrophoretic display apparatus, an organic light-emitting display apparatus, an inorganic light-emitting display apparatus, a field emission display apparatus, a surface-conduction electron-emitter display apparatus, a plasma display apparatus, a cathode ray display apparatus, or the like.

Hereinafter, an organic light-emitting display apparatus is described as an example of a display apparatus according to one or more embodiments, but the display apparatus according to the one or more embodiments is not limited thereto, and various types of display apparatuses may be used.

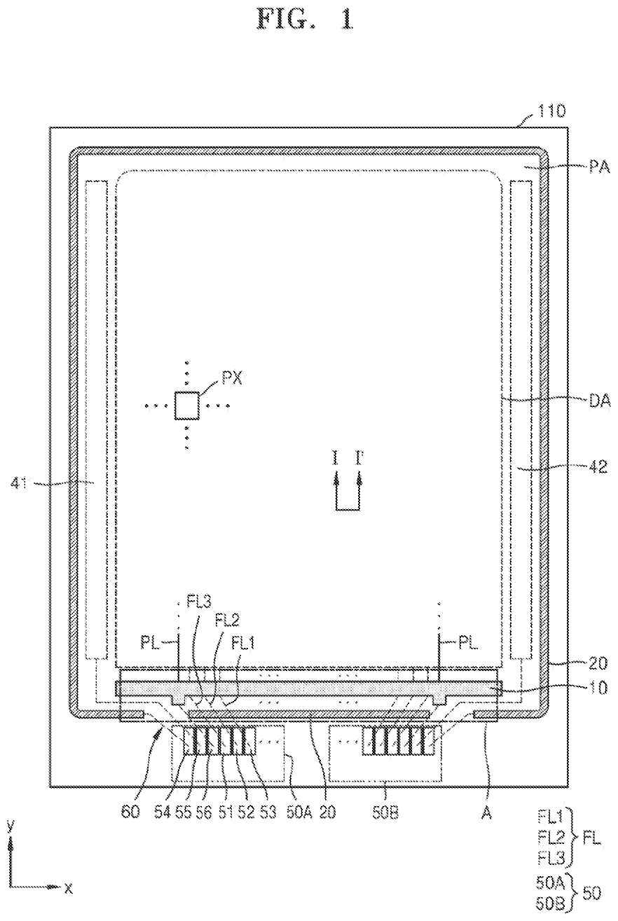

FIG. 1 is a schematic plan view of a display apparatus according to one or more embodiments.

Referring to FIG. 1, a substrate 110 of the display apparatus is divided into a display area DA, and a peripheral area PA around the display area DA. The display area DA includes a plurality of pixels PX, such that an image is realized. The plurality of pixels PX may be connected to a scan line, and to a data line crossing the scan line. Also, the plurality of pixels PX may be connected to a driving voltage line PL.

Each pixel PX may emit light (e.g., red, green, blue, or white light), and may include a light-emitting diode (e.g., an organic light-emitting diode). Also, each pixel PX may further include elements, such as a thin-film transistor (TFT) and a storage capacitor. The display area DA provides a corresponding image through light emitted from the pixels PX. The pixel PX as used herein refers to a subpixel emitting any one of red, green, blue, or white light, as described above.

The peripheral area PA may be an area in which pixels PX are not arranged, and does not provide an image. A first power voltage line 10 and a second power voltage line 20, which apply different power voltages, may be arranged in the peripheral area PA. Also, a first scan driver 41, a second scan driver 42, and a pad portion 50 may be arranged in the peripheral area PA.

The first power voltage line 10 may be arranged in peripheral area PA to correspond to the lower end of the display area DA. A plurality of driving voltage lines PL transmitting driving voltages to the plurality of pixels PX may be connected to the first power voltage line 10, the plurality of pixels PX being arranged in the display area DA. In addition, the first power voltage line 10 may be connected to a pad 56 of the pad portion 50.

The second power voltage line 20 may be arranged in the peripheral area PA to partially surround the display area DA (e.g., in plan view). In some embodiments, the second power voltage line 20 may extend along, except for one side, other sides of the display area DA adjacent to the first power voltage line 10. However, the embodiments are not limited thereto. As shown in FIG. 1, the second power voltage line 20 may be arranged to correspond to all sides of the display area DA. Alternatively, the second power voltage line 20 may be arranged to correspond to one or two sides of the display area DA. Various modifications may be made. The second power voltage line 20 may be connected to a pad 54 of the pad portion 50.

The first scan driver 41 and the second scan driver 42 may be arranged in the peripheral area PA with the display area DA therebetween. That is, the first scan driver 41 may be arranged to correspond to the left side of the display area DA, and the second scan driver 42 may be arranged to correspond to the right side of the display area DA. A scan signal generated by the first scan driver 41 may be provided to some pixels PX through a first scan line, and a scan signal generated by the second scan driver 42 may be provided to some pixels PX through a second scan line.

In some embodiments, the first scan driver 41 and the second scan driver 42 may be arranged on both sides of the display area DA, and may be configured to perform dual scanning. For example, the first scan driver 41 may be configured to generate and transmit scan signals to some of the pixels PX provided in the display area DA, and the second scan driver 42 may be configured to generate and transmit scan signals to others of the pixels PX provided in the display area DA. The first scan driver 41 and the second scan driver 42 may be synchronized by a synchronized clock signal.

In FIG. 1, it is shown that the first and second scan drivers 41 and 42 are arranged on both sides of the display area DA, but the present disclosure is not limited thereto. Various modifications may be made. For example, the first and second scan drivers 41 and 42 may be arranged on only one side of the display area DA, or may not be arranged in the peripheral area PA when the first and second scan drivers 41 and 42 are arranged on a printed circuit board.

The pad portion 50 is arranged in the peripheral area PA, and includes a plurality of pads 51, 52, 53, 54, 55, and 56. The pad portion 50 is exposed without being covered by an insulating layer, and may be electrically connected to a controller, such as a flexible printed circuit board or a driving driver integrated circuit (IC) chip. The controller changes a plurality of image signals, which are externally transmitted, into a plurality of image data signals, and transmits the changed signals to the display area DA through the pad portion 50. Also, the controller may receive a vertical synchronization signal, a horizontal synchronization signal, and a clock signal, may generate control signals for controlling the first and second scan drivers 41 and 42, and may transmit the control signals respectively to the first and second scan drivers 41 and 42 through the pad 55 of the pad portion 50. The controller may transmit different voltages respectively to the first power voltage line 10 and the second power voltage line 20 through the pad portion 50. The pad portion 50 may be connected to a fan-out wire portion FL including first, second, and third fan-out wires FL1, FL2, and FL3, and may be configured to transmit voltages and various signals to the display area DA.

The pad portion 50 may be provided as a plurality of pad portions 50. As shown in FIG. 1, the pad portion 50 may include a first pad portion 50A and a second pad portion 50B.

The first, second, and third fan-out wires FL1, FL2, and FL3 may be respectively connected to the pads 51, 52, 53, 54, 55, and 56 of the pad portion 50, and may be configured to transmit electrical signals to the display area DA, the electrical signals being received from the controller. That is, the first, second, and third fan-out wires FL1, FL2, and FL3 may be connected to the pad portion 50, and may extend to the display area DA.

The first power voltage line 10 may be configured to provide a first power voltage ELVDD to each pixel PX, and the second power voltage line 20 may be configured to provide a second power voltage ELVSS to each pixel PX. For example, the first power voltage ELVDD may be provided to each pixel PX through the driving voltage line PL connected to the first power voltage line 10. The second power voltage ELVSS may be connected, in the peripheral area PA, to an opposite electrode of an organic light-emitting element provided in each pixel PX.

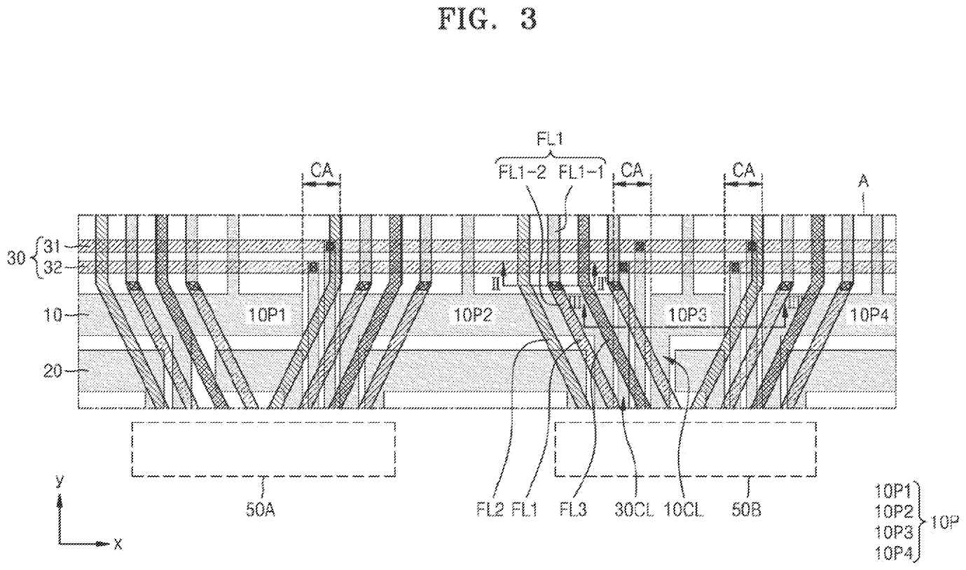

In addition, the first power voltage line 10 according to one or more embodiments may include a plurality of first power patterns 10P (see FIG. 3) spaced apart from each other. Each of the first power patterns 10P may include a first connection line 10CL connected to the pad portion 50. The fan-out wire portion FL may overlap at least a portion of the first power patterns 10P. More detailed descriptions of the first power patterns 10P and the fan-out wire portion FL according to one or more embodiments are provided below.

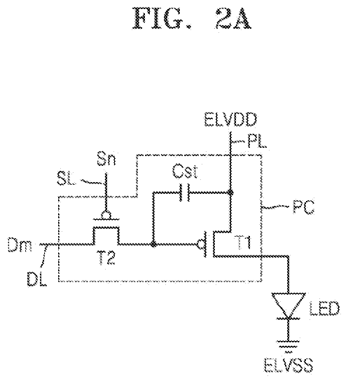

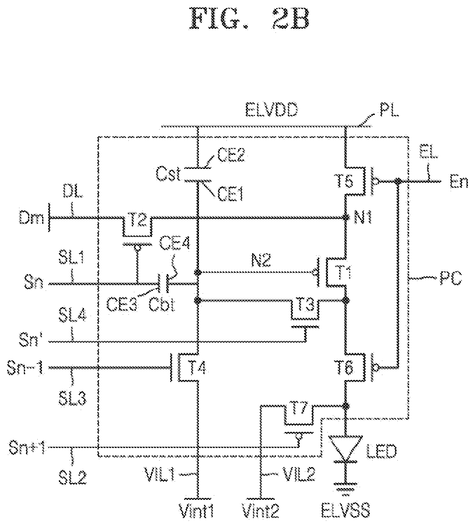

FIGS. 2A and 2B are equivalent circuit diagrams of a pixel circuit PC of the display apparatus according to one or more embodiments.

Referring to FIG. 2A, in one or more embodiments, the pixel circuit PC may include a first transistor T1, a second transistor T2, and a storage capacitor Cst.

The second transistor T2 is a switching transistor that may be connected to a scan line SL and to a data line DL, and may be configured to transmit, to the first transistor T1, a data voltage (or a data signal Dm) input from the data line DL based on a switching voltage (or a switching signal Sn) input from the scan line SL.

The storage capacitor Cst may be connected to the second transistor T2 and to the driving voltage line PL, and may be configured to store a voltage corresponding to a difference between a voltage received from the second transistor T2 and a first power voltage ELVDD supplied to the driving voltage line PL.

The first transistor T1 is a driving transistor, and may be connected to the driving voltage line PL and to the storage capacitor Cst, and may be configured to control a driving current flowing through a light-emitting diode LED from the driving voltage line PL in response to a voltage value stored in the storage capacitor Cst. The light-emitting diode LED may emit light having a corresponding luminance by the driving current. An opposite electrode (e.g., a cathode) of the light-emitting diode LED may receive a second power voltage ELVSS.

Though FIG. 2A illustrates that the pixel circuit PC includes two transistors and one storage capacitor, one or more embodiments are not limited thereto. The number of transistors and the number of storage capacitors may be variously changed according to the design of the pixel circuit PC. For example, the pixel circuit PC may include three or more transistors.

FIG. 2B is a schematic equivalent circuit diagram of a pixel circuit PC electrically connected to a light-emitting diode LED of an electronic apparatus, according to one or more embodiments.

Referring to FIG. 2B, in one or more embodiments, the pixel circuit PC may include a first transistor T1, a second transistor T2, a third transistor T3, a fourth transistor T4, a fifth transistor T5, a sixth transistor T6, a seventh transistor T7, a first storage capacitor Cst, and a second storage capacitor Cbt. The first to seventh transistors T1 to T7 and the first and second storage capacitors Cst and Cbt may be connected to signal lines, a first initialization voltage line VIL1, a second initialization voltage line VIL2, and a driving voltage line PL. The signal lines may include the data line DL, a first scan line SL1, a second scan line SL2, a third scan line SL3, a fourth scan line SL4, and an emission control line EL. In one or more embodiments, at least one of the signal lines, the first and second initialization voltage lines VIL1 and VIL2, and/or the driving voltage line PL may be shared among adjacent pixels.

The driving voltage line PL may be configured to transmit the first power voltage ELVDD to the first transistor T1. The first initialization voltage line VIL1 may be configured to transmit, to the pixel circuit PC, a first initialization voltage Vint1 for initializing the first transistor T1. The second initialization voltage line VIL2 may be configured to transmit, to the pixel circuit PC, a second initialization voltage Vint2 for initializing a light-emitting diode LED.

The first scan line SL1, the second scan line SL2, the third scan line SL3, the fourth scan line SL4, the emission control line EL, the first initialization voltage line VIL1, and the second initialization voltage line VIL2 may extend in an x-direction, and may be arranged in each row to be spaced apart from each other. The data line DL and the driving voltage line PL may extend in a y-direction, and may be arranged in each column to be spaced apart from each other.

For example, among the first to seventh transistors T1 to T7, the third transistor T3 and the fourth transistor T4 may be implemented as n-channel metal-oxide-semiconductor field-effect transistors (MOSFETs) (NMOSs) and the others may be implemented as p-channel MOSFETs (PMOSs). However, one or more embodiments are not limited thereto.

The first transistor T1 may be connected to the driving voltage line PL via the fifth transistor T5, and may be electrically connected to the light-emitting diode LED via the sixth transistor T6. The first transistor T1 may serve as a driving transistor, and may be configured to receive a data signal Dm in response to a switching operation of the second transistor T2, and may supply a driving current to the light-emitting diode LED.

The second transistor T2 may be connected to the first scan line SL1 and the data line DL, and may be connected to the driving voltage line PL via the fifth transistor T5. The second transistor T2 may be turned on in response to a first scan signal Sn received through the first scan line SL1, and may be configured to perform a switching operation of transmitting the data signal Dm transmitted through the data line DL to a node N1.

The third transistor T3 may be connected to the fourth scan line SL4, and may be connected to the light-emitting diode LED via the sixth transistor T6. The third transistor T3 may be turned on in response to a fourth scan signal Sn′ received through the fourth scan line SL4 to diode-connect the first transistor T1.

The fourth transistor T4 may be connected to the third scan line SL3, which is a previous scan line, and the first initialization voltage line VIL1, and may be turned on in response to a third scan signal Sn−1, which is a previous scan signal and received through the third scan line SL3, and may be configured to transmit the first initialization voltage Vint1 from the first initialization voltage line VIL1 to a gate electrode of the first transistor T1, to initialize a voltage of the gate electrode of the first transistor T1. However, one or more embodiments are not limited thereto.

The fifth transistor T5 and the sixth transistor T6 may be connected to the emission control line EL and simultaneously turned on in response to an emission control signal En received through the emission control line EL, and may be configured to form a current path such that the driving current flows from the driving voltage line PL toward the light-emitting diode LED.

The seventh transistor T7 may be connected to the second scan line SL2, which is a next scan line, and the second initialization voltage line VIL2, and may be turned on in response to a second scan signal Sn+1, which is a next scan signal and received through the second scan line SL2, and may be configured to transmit, to the light-emitting diode LED, the second initialization voltage Vint2 from the second initialization voltage line VIL2, to initialize the light-emitting diode LED. However, one or more embodiments are not limited thereto. For example, the seventh transistor T7 may be omitted.

In one or more embodiments, the first storage capacitor Cst may include a first electrode CE1 and a second electrode CE2. In one or more embodiments, the first electrode CE1 may be connected to the gate electrode of the first transistor T1, and the second electrode CE2 may be connected to the driving voltage line PL. The first storage capacitor Cst may be configured to store and maintain a voltage corresponding to a difference between voltages of the driving voltage line PL and the gate electrode of the first transistor T1, such that a voltage applied to the gate electrode of the first transistor T1 may be maintained.

The second storage capacitor Cbt may include a third electrode CE3 and a fourth electrode CE4. The third electrode CE3 may be connected to the first scan line SL1 and to a gate electrode of the second transistor T2. The fourth electrode CE4 may be connected to the gate electrode of the first transistor T1 and to the first electrode CE1 of the first storage capacitor Cst. The second storage capacitor Cbt is a boosting capacitor, and when the first scan signal Sn of the first scan line SL1 is a voltage turning off the second transistor T2, the second storage capacitor Cbt may increase a voltage of a node N2 to reduce a voltage displaying black (a black voltage).

The light-emitting diode LED may include a pixel electrode (e.g., an anode) and an opposite electrode (e.g., a cathode), and the opposite electrode may be configured to receive the second power voltage ELVSS. The light-emitting diode LED may be configured to receive the driving current from the first transistor T1, and may emit light to display an image.

An operation of the pixel circuit PC and a pixel electrically connected to the pixel circuit PC, according to one or more embodiments, is as follows.

During a first initialization period, when the third scan signal Sn−1, which is the previous scan signal, is supplied through the third scan line SL3, the fourth transistor T4 may be turned on in response to the third scan signal Sn−1, and the first transistor T1 may be initialized by the first initialization voltage Vint1 supplied from the first initialization voltage line VIL1.

During a data programming period, when the first scan signal Sn and the fourth scan signal Sn′ are respectively supplied through the first scan line SL1 and the fourth scan line SL4, the second transistor T2 and the third transistor T3 may be turned on in response to the first scan signal Sn and the fourth scan signal Sn′. In this case, the first transistor T1 may be diode-connected by the turned-on third transistor T3, and may be biased in a forward direction. A voltage obtained by compensating for a threshold voltage (Vth) of the first transistor T1 in the data signal Dm supplied from the data line DL may be applied to the gate electrode of the first transistor T1. The first power voltage ELVDD and the compensated voltage may be applied to both ends of the first storage capacitor Cst, and electric charges corresponding to a voltage difference between both ends of the first storage capacitor Cst may be stored in the first storage capacitor Cst.

During an emission period, the fifth transistor T5 and the sixth transistor T6 may be turned on by the emission control signal En supplied from the emission control line EL. The driving current may be generated according to a voltage difference between a voltage of the gate electrode of the first transistor T1 and the first power voltage ELVDD, and the driving current may be supplied to the light-emitting diode LED through the sixth transistor T6.

During a second initialization period, when the second scan signal Sn+1 is supplied through the second scan line SL2, the seventh transistor T7 may be turned on in response to the second scan signal Sn+1, and the light-emitting diode LED may be initialized by the second initialization voltage Vint2 supplied from the second initialization voltage line VIL2.

In one or more embodiments, at least one of the plurality of transistors T1 through T7 may include a semiconductor layer including an oxide, and other transistors may include a semiconductor layer including a silicon. In detail, the first transistor T1 that directly affects a brightness of a display panel is configured to include a silicon semiconductor including polycrystalline silicon having high reliability, and accordingly, a high-resolution display panel may be implemented.

Because an oxide semiconductor has high carrier mobility and low leakage current, a voltage drop thereof is not relatively great despite a relatively long driving time. That is, even during low-frequency driving, a color change of an image according to the voltage drop is not great, and thus, low-frequency driving is possible. As the oxide semiconductor has a small leakage current as described above, at least one of the third transistor T3 and the fourth transistor T4, which are connected to the gate electrode of the first transistor T1, may be used as the oxide semiconductor to reduce or prevent a leakage current that may flow to the gate electrode of the first transistor T1, and also may reduce power consumption. However, one or more embodiments are not limited thereto. All of the plurality of transistors T1 to T7 may include a semiconductor layer including silicon. Also, transistors other than the third transistor T3 and the fourth transistor T4 may include a semiconductor layer including an oxide.

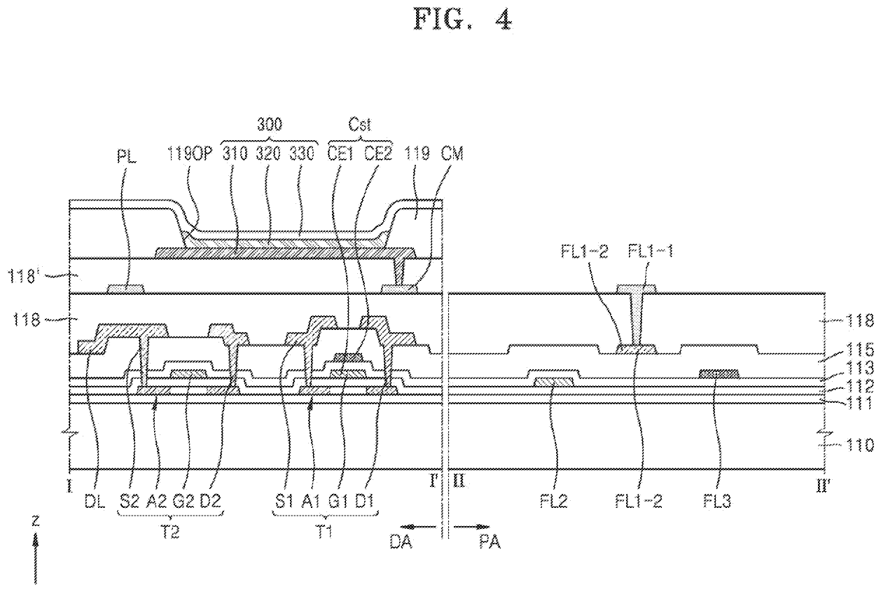

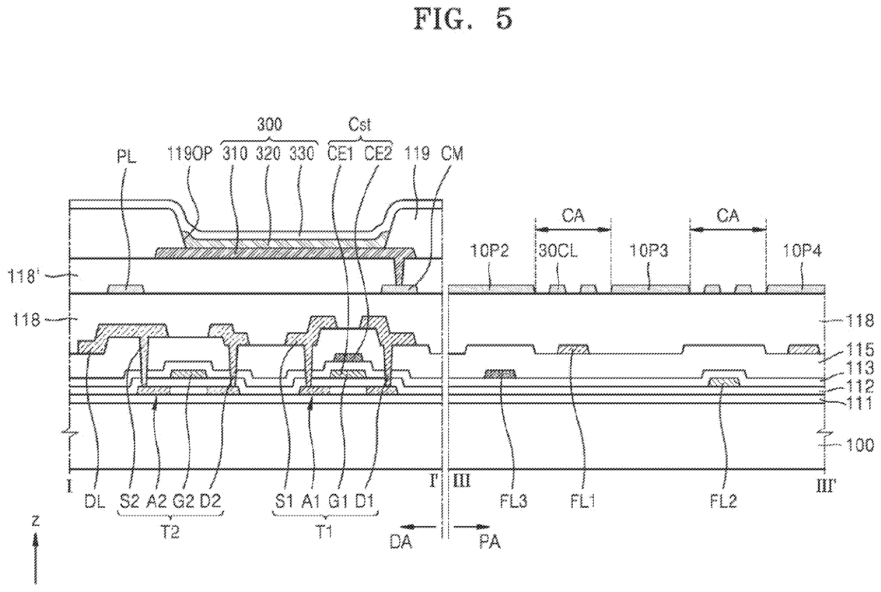

FIG. 3 is an enlarged view of a region A of FIG. 1, FIG. 4 is a schematic diagram of a cross-section of the display apparatus taken along the line I-I′ of FIG. 1 and the line II-II′ of FIG. 3, and FIG. 5 is a schematic diagram of a cross-section of the display apparatus taken along the line I-I′ of FIG. 1 and the line III-III′ of FIG. 3.

First, referring to FIG. 4, a stacked structure of elements included in the display apparatus is described, focusing on the display area DA.

The substrate 110 may include various materials, such as a glass material, a metallic material, or a plastic material. According to one or more embodiments, the substrate 110 may be a flexible substrate and may include, for example, a polymer resin, such as polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), and/or cellulose acetate propionate (CAP).

A buffer layer 111 may be located on the substrate 110 to reduce or block penetration of foreign materials, moisture, or external air from below the substrate 110, and may provide a flat surface over the substrate 110. The buffer layer 111 may include an inorganic material, such as oxide or nitride, an organic material, or an organic/inorganic composite and may have a single-layered or multi-layered structure of an inorganic material and an organic material. A barrier layer that blocks penetration of external air may be further included between the substrate 110 and the buffer layer 111, in one or more embodiments.

The first transistor T1 includes a semiconductor layer A1, a gate electrode G1, a source electrode S1, and a drain electrode D1, and the second transistor T2 includes a semiconductor layer A2, a gate electrode G2, a source electrode S2, and a drain electrode D2. The first transistor T1 may be connected to an organic light-emitting element 300 and function as a driving transistor configured to drive the organic light-emitting element 300. The second transistor T2 may be connected to the data line DL and function as a switching transistor. However, one or more embodiments are not limited thereto. For example, the first transistor T1 may function as a switching transistor, and the second transistor T2 may function as a driving transistor. Though two transistors are shown in FIG. 4, one or more embodiments are not limited thereto. The number of transistors may be variously modified, such as 2 to 7.

The semiconductor layers A1 and A2 may each include amorphous silicon or polysilicon. In another embodiment, the semiconductor layers A1 and A2 may each include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), and/or zinc (Zn). The semiconductor layers A1 and A2 may each include a channel region, as well as a source region and a drain region doped with impurities.

Gate electrodes G1 and G2 are respectively arranged over the semiconductor layers A1 and A2 with a first gate-insulating layer 112 therebetween. The gate electrodes G1 and G2 may each include molybdenum (Mo), aluminum (Al), copper (Cu), and/or Ti and may each include a single layer or multi-layer. For example, the gate electrodes G1 and G2 may each include a single Mo layer.

The first gate-insulating layer 112 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), and/or zinc oxide (ZnO).

A second gate-insulating layer 113 may be provided to cover the gate electrodes G1 and G2. The second gate-insulating layer 113 may include SiO₂, SiN_{X}, SiON, Al₂O₃, TiO₂, Ta₂O₅, HfO₂, and/or ZnO₂.

The first electrode CE1 of the storage capacitor Cst may overlap the first transistor T1. For example, the gate electrode G1 of the first transistor T1 may function as the first electrode CE1 of the storage capacitor Cst.

The second electrode CE2 of the storage capacitor Cst overlaps the first electrode CE1 with the second gate-insulating layer 113 therebetween. In this case, the second gate-insulating layer 113 may function as a dielectric layer of the storage capacitor Cst. The second electrode CE2 may include a conductive material including Mo, Al, Cu, and/or Ti and may include a single layer or multi-layer including the above conductive material. For example, the second electrode CE2 may include a single Mo layer or a multi-layer of Mo/Al/Mo.

The source electrodes S1 and S2 and the drain electrodes D1 and D2 are located on an interlayer insulating layer 115. The source electrodes S1 and S2 and the drain electrodes D1 and D2 may each include a conductive material including Mo, Al, Cu, and/or Ti, and may each include a single layer or multi-layer including the above conductive material. For example, the source electrodes S1 and S2 and the drain electrodes D1 and D2 may each have a multi-layered structure of Ti/Al/Ti.

A planarization layer 118 may be located on the source electrodes S1 and S2 and the drain electrodes D1 and D2, and an upper planarization layer 118′ may be located on the planarization layer 118. An additional wire and an intermediate wire CM may be further included in the upper planarization layer 118′.

The planarization layer 118 may include a general-purpose polymer, such as benzocyclobutene (BCB), polyimide, hexamethyldisiloxane (HMDSO), polymethylmethacrylate (PMMA) or polystyrene (PS), a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and/or any blend thereof. The planarization layer 118 may include an inorganic material. The planarization layer 118 may include SiO₂, SiN_{X}, SiON, Al₂O₃, TiO₂, Ta₂O₅, HfO₂ , and/or ZnO₂. When the planarization layer 118 includes an inorganic material, chemical mechanical polishing may be performed when necessary. Moreover, the planarization layer 118 may include both an organic material and an inorganic material.

The upper planarization layer 118′ may include an organic material and/or an inorganic material. For example, the organic material may include a general-purpose polymer, such as BCB, polyimide, HMDSO, PMMA or PS, a polymer derivative having a phenol-based group, an acrylic polymer, an imide-based polymer, an aryl ether-based polymer, an amide-based polymer, a fluorine-based polymer, a p-xylene-based polymer, a vinyl alcohol-based polymer, and/or any blend thereof. The inorganic material may include SiO₂, SiNₓ, SiON, Al₂O₃, TiO₂, Ta₂O₅, HfO₂, and/or ZnO₂. The upper planarization layer 118′ may have a single-layered or multi-layered structure.

The additional wire located on the planarization layer 118 may function as the driving voltage line PL configured to transmit a driving voltage or the data line DL configured to transmit a data signal. The additional wire may be connected to the data line DL through a contact hole defined in the planarization layer 118, in one or more embodiments. Also, a pixel electrode 310 of an organic light-emitting element 300 may be connected to the first transistor T1 through the intermediate wire CM located on the planarization layer 118. The additional wire and the intermediate wire CM may include Mo, Al, Cu, and/or Ti and may include a multi-layer and single layer.

The upper planarization layer 118′ may have a flat upper surface, such that the pixel electrode 310 may be formed flat. In the display area DA of the substrate 110, the organic light-emitting element 300 is located on the upper planarization layer 118′. The organic light-emitting element 300 includes the pixel electrode 310, an intermediate layer 320 including an organic emission layer, and an opposite electrode 330.

The pixel electrode 310 may be a (semi-)transmissive electrode or a reflective electrode. In some embodiments, the pixel electrode 310 may include a reflective layer and a transparent or semi-transparent electrode layer formed on the reflective layer, the reflective layer including silver (Ag), magnesium (Mg), Al, platinum (Pt), palladium (Pd), gold (Au), nickel (Ni), neodymium (Nd), iridium (Ir), Cr, and/or any compound thereof. The transparent or semi-transparent electrode layer may include at least one selected from the group consisting of indium tin oxide (ITO), indium zinc oxide (IZO), ZnO, indium oxide (In₂O₃), indium gallium oxide (IGO), and/or aluminum zinc oxide (AZO).

A pixel-defining layer 119 may be located on the planarization layer 118, and the pixel-defining layer 119 has an opening corresponding to each sub-pixel in the display area DA, for example, an opening portion 119OP exposing at least a central portion of the pixel electrode 310, and thus may define an emission area of a pixel. Also, the pixel-defining layer 119 may increase a distance between an edge of the pixel electrode 310 and the opposite electrode 330 over the pixel electrode 310 to reduce or prevent the likelihood of an arc or the like from occurring on the edge of the pixel electrode 310. The pixel-defining layer 119 may include one or more organic insulating materials selected from the group consisting of polyimide, polyamide, an acrylic resin, BCB, and/or a phenol-based resin, and may be formed by a method, such as spin coating.

The intermediate layer 320 of the organic light-emitting element 300 may include an organic emission layer. The organic emission layer may include an organic material including a fluorescent or phosphorous material emitting red, green, blue, or white light. The organic emission layer may include a low molecular weight organic material or a polymer organic material, and/or a functional layer, such as a hole transport layer (HTL), a hole injection layer (HIL), an electron transport layer (ETL), and/or an electron injection layer (EIL), may be selectively further arranged under and over the organic emission layer. The intermediate layer 320 may correspond to each of a plurality of pixel electrodes 310. However, one or more embodiments are not limited thereto. Various modifications may be made. For example, the intermediate layer 320 may include an integrated layer over the plurality of pixel electrodes 310.

The opposite electrode 330 may include a transmissive electrode or a reflective electrode. In some embodiments, the opposite electrode 330 may include a transparent or semi-transparent electrode and may include a metal thin-film that has a low work function and includes lithium (Li), calcium (Ca), LiF/Ca, LiF/Al, Al, Ag, Mg, and/or any compound thereof. Also, a transparent conductive oxide (TCO) film including ITO, IZO, ZnO, and/or In₂O₃ may be further arranged over the metal thin-film. The opposite electrode 330 may be arranged over the display area DA and the peripheral area PA, and may be arranged over the intermediate layer 320 and the pixel-defining layer 119. The opposite electrode 330 may be integrally formed as a single body with a plurality of organic light-emitting elements 300 to correspond to the plurality of pixel electrodes 310.

Referring to FIG. 3, the display apparatus may include the pad portion 50, the fan-out wire portion FL, the first power voltage line 10, the second power voltage line 20, a third power voltage line 30, the first connection line 10CL, and a third connection line 30CL.

The pad portion 50 may be arranged in the peripheral area PA and may be configured to transmit different voltages to the first power voltage line 10 and the second power voltage line 20, respectively. The pad portion 50 may be connected to a plurality of fan-out wire portions FL and may be configured to voltages and various signals to the display area DA. The pad portion 50 may be provided as a plurality of pad portions 50. The pad portion 50 may include a first pad portion 50A and a second pad portion 50B. In one or more other embodiments, the pad portion 50 may be provided as three or more pad portions 50.

The fan-out wire portion FL may be connected to the pad portion 50. The fan-out wire portion FL may include the first, second, and third fan-out wires FL1, FL2, and FL3. Each of the first, second, and third fan-out wires FL1, FL2, and FL3 may be connected to the first pad portion 50A or the second pad portion 50B. The first, second, and third fan-out wires FL1, FL2, and FL3 of the fan-out wire portion FL may be connected to wires in the display area DA, and may be configured to transmit electrical signals from a plurality of pads of the pad portion 50 to pixels of the display area DA, respectively.

Referring to FIGS. 3 and 4 together, the first, second, and third fan-out wires FL1, FL2, and FL3 may be arranged on different layers. The first fan-out wire FL1 may be located on the interlayer insulating layer 115, the second fan-out wire FL2 may be located on the first gate-insulating layer 112, and the third fan-out wire FL3 may be located on the second gate-insulating layer 113.

The first fan-out wire FL1 and the source electrodes S1 and S2 of the first and second transistors T1 and T2 may be arranged at the same layer, and may include the same material. The second fan-out wire FL2 and the first electrode CE1 of the storage capacitor Cst may be arranged at the same layer, and may include the same material. The third fan-out wire FL3 and the second electrode CE2 of the storage capacitor Cst may be arranged at the same layer, and may include the same material.

For simplicity of illustration, the first, second, and third fan-out wires FL1, FL2, and FL3 are shown spaced apart from each other, but one or more embodiments are not limited thereto. For example, the first fan-out wire FL1 may partially overlap the second fan-out wire FL2 and/or the third fan-out wire FL3.

The fan-out wire portion FL may overlap the first power voltage line 10 and the third power voltage line 30. The first fan-out wire FL1 may include a (1-1)st fan-out wire FL1-1 and a (1-2)st fan-out wire FL1-2, the (1-1)st fan-out wire FL1-1 being arranged at the same layer as the source electrodes S1 and S2 in an area overlapping the first power voltage line 10, and the (1-2)st fan-out wire FL1-2 being arranged on a different layer from the (1-1)st fan-out wire FL1-1 in an area overlapping the third power voltage line 30. The (1-2)st fan-out wire FL1-2 may be arranged at the same layer as the first electrode CE1, the second electrode CE2, or the intermediate wire CM. The (1-1)st fan-out wire FL1-1 and the (1-2)st fan-out wire FL1-2 may be electrically connected to each other through a contact hole. Accordingly, the first fan-out wire FL1 may overlap both the first power voltage line 10 and the third power voltage line 30.

The first, second, and third fan-out wires FL1, FL2, and FL3 according to one or more embodiments are alternately arranged on different layers to thereby reduce resistance of the peripheral area PA and wires. Also, a fan-out wire including the same material as the source electrodes S1 and S2 having relatively high conductivity is included, and thus, scan-on time may be reduced and high-speed operation may be realized.

Referring to FIGS. 3 and 5 together, the first power voltage line 10 may be arranged in the peripheral area PA. The first power voltage line 10 may be between the display area DA and the pad portion 50 (e.g., in plan view). The first power voltage line 10 may be arranged over the planarization layer 118. The first power voltage line 10 and the intermediate wire CM may be arranged at the same layer, and may include the same material. Accordingly, the first power voltage line 10 may overlap the first, second, and third fan-out wires FL1, FL2, and FL3.

The third power voltage line 30 may be arranged in the peripheral area PA. The third power voltage line 30 may be between the display area DA and the first power voltage line 10. The third power voltage line 30 may be arranged extending in a first direction. The third power voltage line 30 and the source electrodes S1 and S2 may be arranged at the same layer, and may include the same material. The third power voltage line 30 may include a first initialization voltage supply line 31 configured to supply the first initialization voltage Vint1, and/or a second initialization voltage supply line 32 configured to supply the second initialization voltage Vint2.

The third connection line(s) 30CL may be connected to the third power voltage line 30. The third connection line 30CL may extend in a second direction, and may be connected to the pad portion 50. The third connection line 30CL may be connected to the first pad portion 50A and/or the second pad portion 50B. The third connection line 30CL may transmit a voltage from the pad portion 50 to the third power voltage line 30.

The third connection line 30CL and the first power voltage line 10 may be arranged at the same layer, and may include the same material. The first power voltage line 10 may include a connection area CA through which the third connection line 30CL extending in the second direction passes. That is, the first power voltage line 10 may have a shape of being disconnected by, or discontinuous at, the third connection line 30CL. The first power voltage line 10 may include a plurality of first power patterns 10P separated from each other with the third connection line(s) 30CL therebetween (e.g., respectively). The first power patterns 10P may be arranged in the first direction. A portion 10P3 of the first power patterns 10P may be between a plurality of third connection lines 30CL connected to one pad portion (e.g., the second pad portion 50B).

When the first power voltage line 10 includes the first power patterns 10P spaced apart from each other, a portion of the first power patterns 10P may be disconnected from the pad portion 50. Accordingly, because an area to which the first power voltage ELVDD is not directly applied occurs in the display area DA, luminance uniformity of the display apparatus may deteriorate.

In the display apparatus according to one or more embodiments, the first power voltage line 10 includes the first power patterns 10P spaced apart from each other, and each of the first power patterns 10P includes the first connection line 10CL connected to the pad portion 50. The first connection line 10CL may be a portion of the first power patterns 10P each extending in the second direction and being connected to the first pad portion 50A or the second pad portion 50B. Accordingly, the luminance uniformity of the display apparatus may be improved.

The second power voltage line 20 may be arranged in the peripheral area PA. The second power voltage line 20 and the first power voltage line 10 may be arranged at the same layer, and may include the same material. The second power voltage line 20 may overlap the fan-out wire portion FL. When a portion of the second power voltage line 20 is between the first power voltage line 10 and the pad portion 50, in some areas, like the first power voltage line 10, the second power voltage line 20 may be provided as a plurality of second power patterns. The second power patterns may be spaced apart from each other by the first connection line 10CL or the third connection line 30CL.

In addition, referring to FIG. 3, because the third connection line(s) 30CL is arranged in the connection area CA, and the third connection line 30CL and the first power patterns 10P are arranged at the same layer, the first power patterns 10P may not be connected to the display area DA in the connection area CA. That is, it may be difficult for an area of the display area DA, corresponding to an upper portion of the connection area CA, to directly receive the first power voltage ELVDD.

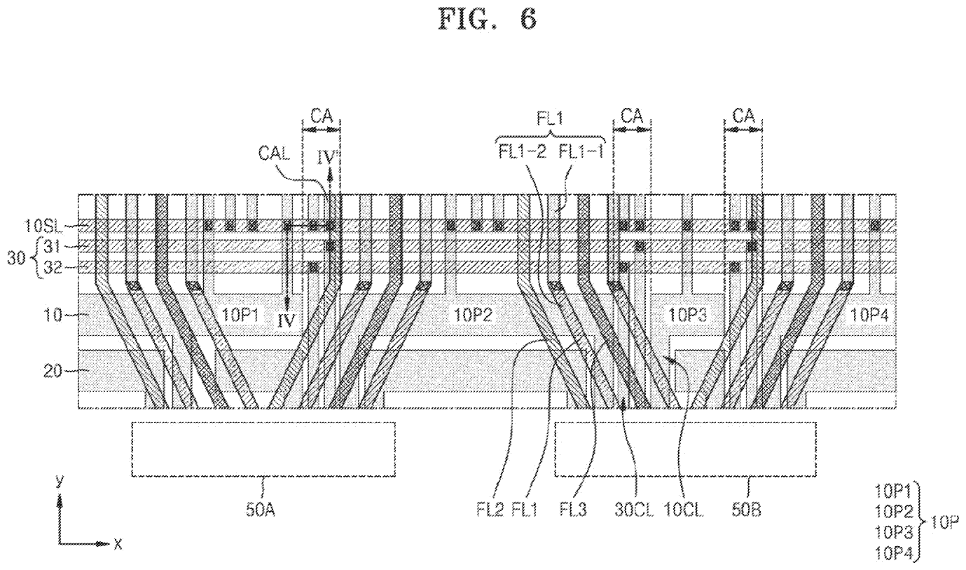

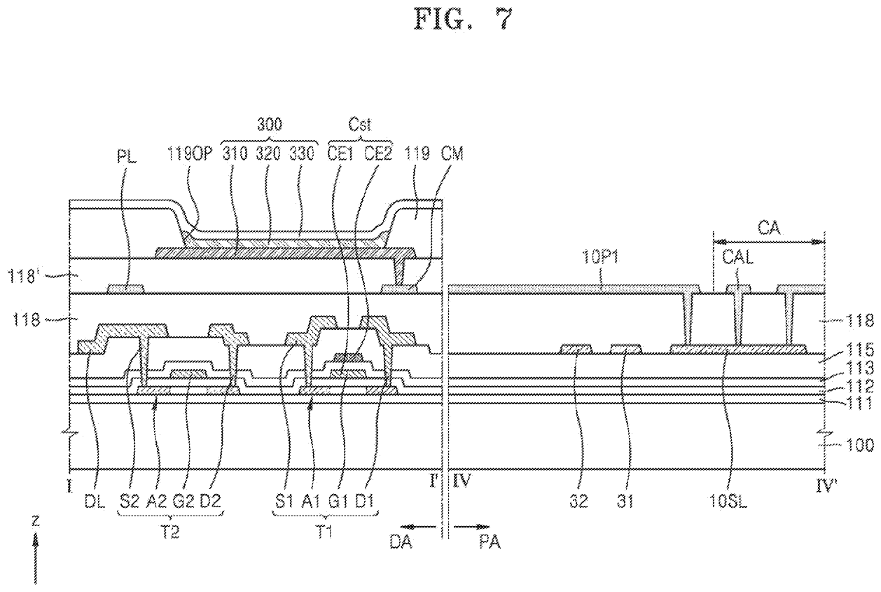

FIG. 6 is an enlarged view of a region A of FIG. 1, and FIG. 7 is a schematic diagram of a cross-section of the display apparatus taken along the line I-I′ of FIG. 1 and the line IV-IV′ of FIG. 6. Like reference numerals as those of FIGS. 3 and 4 denote like elements, and thus, repeated descriptions thereof will be omitted.

Referring to FIGS. 6 and 7 together, a first power sub-line 10SL may be between the display area DA and the first power voltage line 10. The first power sub-line 10SL may be between the display area DA and the third power voltage line 30. The first power sub-line 10SL may extend in the first direction. The first power sub-line 10SL and the first power patterns 10P may be arranged on different layers. The first power sub-line 10SL may be arranged at the same layer, and may include the same material as the source electrodes S1 and S2 of the first and second transistors T1 and T2.

The first power sub-line 10SL may be electrically connected to at least one of the first power patterns 10P. The first power sub-line 10SL may be connected to a connection area line CAL arranged in the connection area CA. The connection area line CAL may extend in the second direction, and may extend from the peripheral area PA to the display area DA.

The first power sub-line 10SL may be configured to receive the first power voltage ELVDD from the first power patterns 10P connected to the pad portion 50 through the first connection line 10CL, and also may directly apply the first power voltage ELVDD to the area of the display area DA, corresponding to the upper portion of the connection area CA through the connection area line CAL. Accordingly, the luminance uniformity and display quality of the display apparatus may be improved. The first power sub-line 10SL may be configured to apply the first power voltage ELVDD to the display area DA through a wire connected to the display area DA even in an area other than the connection area CA.

The display apparatus according to one or more embodiments may include the pad portion 50, the fan-out wire portion FL including the first, second, and third fan-out wires FL1, FL2, and FL3), and the first power voltage line 10 overlapping the fan-out wire portion FL and including the plurality of first power patterns 10P. The first, second, and third fan-out wires FL1, FL2, and FL3 may be arranged on different layers. Each of the first power patterns 10P may include the first connection line 10CL connected to the pad portion 50, and may be configured to receive the first power voltage ELVDD.

The third power voltage line 30 may be between the first power voltage line 10 and the display area DA, and the third power voltage line 30 may be connected to the pad portion 50 through the third connection line 30CL. The third connection line 30CL may be arranged in the connection area CA between the first power patterns 10P. The first power patterns 10P may be spaced apart from each other by the third connection line 30CL.

The first power sub-line 10SL may be between the third power voltage line 30 and the display area DA. The first power sub-line 10SL may be connected to at least one of the first power patterns 10P, and may be configured to receive the first power voltage ELVDD. The first power sub-line 10SL may be configured to apply the first power voltage ELVDD to the display area DA by the connection area line CAL arranged in the connection area CA, and extending to the display area DA.

As described above, the one or more embodiments have been described with reference to the accompanying drawings, but the embodiments should be considered in a descriptive sense only. Those of ordinary skill in the art will understand that various modifications and changes to the embodiments may be made therefrom. Therefore, the true technical scope of protection of the disclosure should be defined by the technical spirit of the appended claims.

According to the one or more embodiments described above, a display apparatus may include fan-out wires stacked in a plurality of layers to reduce a peripheral area and a plurality of first power patterns spaced apart from each other and each connected to a pad portion, thereby providing excellent display quality. However, the scope of the disclosure is not limited to the above effects.

It should be understood that the embodiments described herein should be considered in a descriptive sense only and not for purposes of limitation. Descriptions of features or aspects within each of the embodiments should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

What is claimed is:

1. A display apparatus comprising:
a substrate comprising a display area configured to display an image using a pixel, and a peripheral area at least partially surrounding the display area;
a pad portion in the peripheral area, and comprising pads;
a first power voltage line between the display area and the pad portion in plan view, and comprising first power patterns spaced apart from each other; and
a fan-out wire portion connected between the pad portion and the display area, and overlapping at least a portion of the first power patterns,
wherein the fan-out wire portion comprises a first fan-out wire, a second fan-out wire, and a third fan-out wire, the second fan-out wire being at a different layer from the first fan-out wire, and the third fan-out wire being at a different layer from the first fan-out wire and from the second fan-out wire.

2. The display apparatus of claim 1, wherein the first power patterns are arranged in a first direction.

3. The display apparatus of claim 1, wherein the first power patterns comprise a first connection line connected to the pad portion.

4. The display apparatus of claim 1, further comprising:
a third power voltage line extending in a first direction between the display area and the first power voltage line; and
a third connection line connected to the third power voltage line, and extending in a second direction between the first power patterns.

5. The display apparatus of claim 4, wherein the third connection line and the first power patterns are at a same layer.

6. The display apparatus of claim 1, further comprising a first power sub-line extending in a first direction between the first power voltage line and the display area,
wherein the first power sub-line is electrically connected to at least one of the first power patterns.

7. The display apparatus of claim 6, wherein the first power sub-line is at a different layer from the first power patterns.

8. The display apparatus of claim 1, further comprising:
a transistor and a storage capacitor in the display area, the transistor comprising a semiconductor layer, a gate electrode, a source electrode, and a drain electrode, and the storage capacitor comprising a first electrode and a second electrode; and
a driving voltage line above the transistor in the display area, and connected to the first power voltage line.

9. The display apparatus of claim 8, wherein the first fan-out wire and the source electrode are at a same layer, and
wherein the first power patterns and the driving voltage line are at a same layer.

10. The display apparatus of claim 9, wherein the second fan-out wire and the first electrode are at a same layer, and
wherein the third fan-out wire and the second electrode are at a same layer.

11. The display apparatus of claim 1, further comprising a second power voltage line partially overlapping the fan-out wire portion, the second power voltage line and the first power patterns being at a same layer.

12. The display apparatus of claim 1, further comprising an organic light-emitting element in the display area, and comprising a pixel electrode, an intermediate layer comprising an organic emission layer, and an opposite electrode.

13. A display apparatus comprising:
a substrate comprising a display area for displaying an image using a pixel, and a peripheral area at least partially surrounding the display area;
a pad portion in the peripheral area, and comprising pads;
a first power voltage line comprising first power patterns arranged in a first direction in the peripheral area, and connected to the pad portion;
a driving voltage line electrically connected to the first power voltage line, and extending to the display area;
a third power voltage line extending in the first direction in the peripheral area; and
a third connection line connecting the third power voltage line to the pad portion, crossing between the first power patterns, and at a same layer as the first power patterns.

14. The display apparatus of claim 13, further comprising a first fan-out wire extending from the pad portion to the display area, and overlapping at least a portion of the first power patterns.

15. The display apparatus of claim 14, further comprising a transistor in the display area, and comprising a semiconductor layer, a gate electrode, a source electrode, and a drain electrode,
wherein the first fan-out wire and the source electrode are at a same layer.

16. The display apparatus of claim 15, further comprising a second power voltage line partially overlapping the first fan-out wire, and at a same layer as the first power patterns.

17. The display apparatus of claim 13, further comprising a first power sub-line extending in the first direction between the first power voltage line and the display area, and electrically connected to at least one of the first power patterns.

18. The display apparatus of claim 17, wherein the first power sub-line is connected to the driving voltage line.

19. The display apparatus of claim 17, wherein the first power sub-line is at a different layer from the first power patterns.

20. The display apparatus of claim 13, further comprising an organic light-emitting element in the display area, and comprising a pixel electrode, an intermediate layer comprising an organic emission layer, and an opposite electrode.
